(19) United States
(12) Patent Application Publication
(10) Pub. No.: US 2026/0353729 A1
(43) Pub. Date: Nov. 5, 2026

(54) LDMOS DEVICE HAVING A WAVY STRUCTURE AND METHODS OF MAKING THEREOF

(71) Applicant: GlobalFoundries Singapore Pte. Ltd., Singapore (SG)

(72) Inventors: YONG WAH SEE, Singapore (SG); GUOWEI ZHANG, Singapore (SG)

(21) Appl. No.: 19/196,803

(22) Filed: May 2, 2025

(51) Int. Cl. H10D 62/10; H10D 30/01; H10D 30/65; H10D 62/13; H10D 64/27; H10W 10/00; H10W 10/13

(52) U.S. Cl. CPC H10D 62/124; H10D 30/0281; H10D 30/65; H10D 62/155; H10D 62/159; H10D 64/514; H10D 64/518; H10W 10/012; H10W 10/13

(57) ABSTRACT

Laterally diffused metal oxide semiconductor (LDMOS) devices having a wavy structure and methods of making the same are provided. LDMOS devices can include a substrate having a deep well region and a device well within the deep well region. The deep well region can further include an isolation region and a drain contact region adjacent to the isolation region. The device well can include a body contact region and a source contact region adjacent to the body contact region. A gate dielectric layer is over a portion of the deep well region, and a gate electrode is over the gate dielectric layer. The drain contact region, the isolation region, the device well, the body contact region and the source contact region each have a wavy top surface.

### FIELD OF THE INVENTION

The present invention relates generally to laterally diffused metal oxide semiconductor (LDMOS) devices, and more particularly to LDMOS devices having a wavy structure and methods of making the same.

### BACKGROUND

In high voltage and power applications, LDMOS transistors are widely used due to their high drain-to-source breakdown voltage, which is a result of a sufficiently long drift region between the gate and the drain. However, the performance of LDMOS transistors can be adversely affected by relatively high drain-to-source on-resistance values, which results in reduced switching speeds and higher energy losses.

Improved structures and methods for LDMOS transistors with better performance are therefore desired.

### SUMMARY

According to an embodiment of the invention, a transistor comprising a deep well region, the deep well region comprising a device well, a drain contact region, an isolation region adjacent to the drain contact region, a body contact region and a source contact region adjacent to the body contact region. A gate dielectric layer is over a portion of the deep well region, the gate dielectric layer extending partially over the device well and partially over the isolation region. A gate electrode is over the gate dielectric layer, wherein the device well, the drain contact region, the isolation region, the body contact region and the source contact region each has a wavy top surface.

According to another embodiment of the invention, a laterally diffused metal oxide semiconductor (LDMOS) transistor comprising an active region comprising a deep well region, a drain contact region, an isolation region adjacent to the drain contact region, a device well including a body contact region, and a source contact region adjacent to the body contact region. A gate dielectric layer is over a portion of the active region, the gate dielectric layer extending partially over the device well and partially over the isolation region. A gate electrode is over the gate dielectric layer, wherein the active region has a wavy top surface comprising of parallel ridges and grooves extending from the body contact region to the drain contact region and the parallel ridges and grooves are alternately arranged.

According to yet another embodiment of the invention, it is provided a method of fabricating a transistor comprising forming a deep well region in a substrate, forming a wavy top surface for the deep well region, forming a device well within the deep well region, and forming an isolation region within the deep well region. The method also comprises forming a gate dielectric layer over a portion of the device well, the gate dielectric layer extending partially over the device well and partially over the isolation region, and forming a gate electrode over the gate dielectric layer. The method further comprises forming a drain contact region within the deep well region, forming a body contact region within the device well, and forming a source contact region within the device well, adjacent to the body contact region, wherein the drain contact region, the isolation region, the device well, the body contact region and the source contact region each has a wavy top surface.

### BRIEF DESCRIPTION OF THE DRAWINGS

The accompanying drawings illustrate examples of various non-limiting embodiments of the invention and constitute a part of the specification. The drawings, along with the above general description of the invention, and the following detailed description of the various embodiments, serve to explain the examples of the non-limiting embodiments of the invention. In the drawings, like reference numerals generally refer to like features in the various views.

FIG. 1 shows a simplified cross-sectional view of a transistor 100, according to an exemplary embodiment of the disclosure.

FIG. 1A shows a simplified plan view of a transistor 100 across line P-P′ in FIG. 1, according to an exemplary embodiment of the disclosure.

FIG. 2 shows a simplified three-dimensional view of a transistor 100, according to an exemplary embodiment of the disclosure.

FIG. 2A shows a simplified cross-sectional view of a transistor 100 across line A-A′ in FIG. 2, according to an exemplary embodiment of the disclosure.

FIG. 2B shows a simplified cross-sectional view of a section of a transistor 100 across line B-B′ in FIG. 2, according to an exemplary embodiment of the disclosure.

FIG. 2C shows a simplified cross-sectional view of a section of a transistor 100 across line C-C′ in FIG. 2, according to an exemplary embodiment of the disclosure.

FIG. 3-12B show simplified cross-sectional views representing exemplary process steps for fabricating the section of a transistor 100 shown in FIG. 1, according to exemplary embodiments of the invention.

For simplicity and clarity of illustration, the drawings illustrate the general manner of construction, and certain descriptions and details of well-known features and techniques may be omitted to avoid unnecessarily obscuring the discussion of the described embodiments of the device. Additionally, elements in the drawings are not necessarily drawn to scale and the dimensions of some of the elements in the drawings may be exaggerated relative to other elements to help improve understanding of the embodiments of the device.

### DETAILED DESCRIPTION

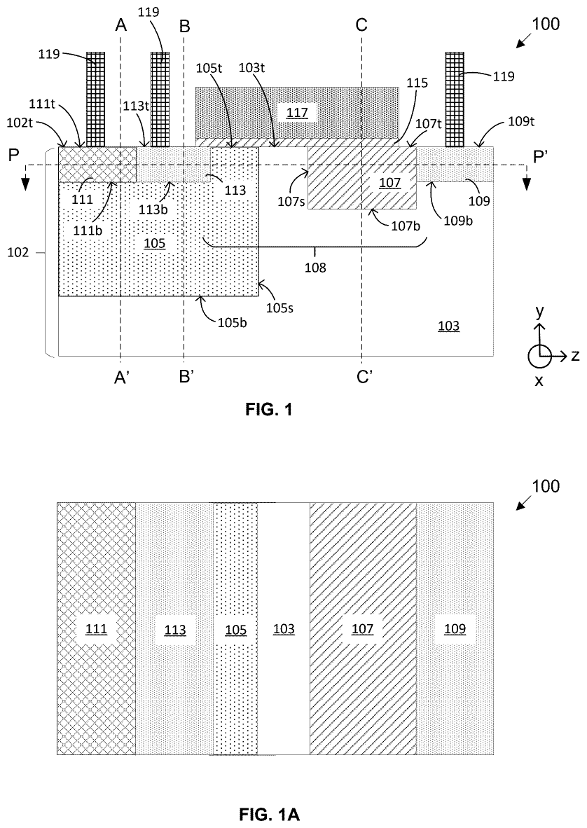

According to an exemplary embodiment of the disclosure, FIG. 1 shows a simplified cross-sectional view of a section of a transistor 100, and FIG. 1A shows a simplified plan view of a transistor 100 across line P-P′ in FIG. 1. The transistor 100 may include an active region 102 within a substrate 101 (not shown). The substrate 101 may include but is not limited to silicon, germanium, silicon germanium (SiGe), silicon carbide, gallium arsenide, silicon-on-insulator (SOI) substrate, or any other suitable integrated circuit (IC) semiconductor substrates. In some embodiments, substrate 101 may include a p-type substrate. The active region 102 may include a number of doped regions, including a deep well region 103 in the substrate 101, a device well 105 in the deep well region 103, a drain contact region 109, a body contact region 111 and a source contact region 113. In some embodiments, for example, in a N-type LDMOS transistor, the device well 105 may function as a body region and the body contact region 111 and source contact region 113 may be in the device well 105, while the drain contact region 109 may be in the deep well region 103, spaced from the device well 105. The LDMOS transistor may also include an isolation region 107 positioned between the drain contact region 109 and the source contact region 113, the isolation region 107 being spaced from the device well 105 by a portion of the deep well region 103, as can be seen in FIG. 1A. In other embodiments, for example, in a P-type LDMOS (not shown), the body contact region 111 and source contact region 113 may be in the deep well region 103 and spaced from the device well 105, while the drain contact region 109 may be in the device well 105. The isolation region 107 may be in the device well 105 and spaced from the source contact region 113.

The dopant types and the dopant concentrations of the doped regions may differ in various embodiments of the invention. In some embodiments, the dopant concentration of the drain contact region 109 may be higher than that of the deep well region 103, and the dopant concentrations of the body contact region 111 and the source contact region 113 may both be higher than the dopant concentration of the device well 105. The dopant concentration of the device well 105 may also be higher than the dopant concentration of the deep well region 103. The dopant type for each doped region is dependent on the desired type of transistor. In an embodiment where a N-type LDMOS transistor is desired, the deep well region 103, the source contact region 113 and the drain contact region 109 may have dopants of a first polarity, for example, n-type dopants such as arsenic (As), phosphorus (P), or any other suitable n-type dopants. The device well 105 and the body contact region 111 may have dopants of a second polarity, for example, p-type dopants such as boron (B), or any other suitable p-type dopants. In other embodiments where a P-type LDMOS transistor (not shown) is desired, the deep well region 103 and the body contact region 111 may have dopants of a first polarity, for example, n-type dopants, while the source contact region 113 and the drain contact region 109 may have dopants of a second polarity, for example, p-type dopants. The drain contact region 109 may also be in a device well 105 having dopants of the second polarity.

The transistor 100 may include an isolation region 107 in the deep well region 103, the isolation region 107 being spaced from the device well 105. The isolation region 107 may have a bottom interface 107b and a side interface 107s with the deep well region 103. The drain contact region 109 is adjacent to the isolation region 107 and electrically connected to a contact 119. In some embodiments, the drain contact region 109 may be directly contacting the isolation region 107. The drain contact region 109 may have a bottom interface 109b with the deep well region 103. The body contact region 111 and the source contact region 113 are in the device well 105, and the source contact region 113 is laterally adjacent to the body contact region 111. The body contact region 111 may have a bottom interface 111b with the device well 105, and the source contact region 113 may also have a bottom interface 113b with the device well 105. The device well 105 may have a bottom interface 105b and a side interface 105s with the deep well region 103.

The active region 102 may have a top surface 102t. The device well 105 may have a top surface 105t that is aligned with a top surface 111t of the body contact region 111 and a top surface 113t of the source contact region 113 in some embodiments. The top surface 105t of the device well 105 may also be aligned with a top surface 103t of the deep well region 103. The top surface 102t of the active region 102 may comprise the top surfaces of the body contact region 111, the source contact region 113 and the device well 105, which may be 111t, 113t and 105 respectively. The top surface 102t of the active region may also comprise the top surfaces of the deep well region 103, the isolation region 107 and the drain contact region 109, which may be 103t, 107t and 109t respectively. The active region 102 may include a channel region 108, extending from the source contract region 113 to the drain contact region 109. The channel region 108 may comprise a channel width parallel to the x-axis, and a channel length parallel to the z-axis.

A contact 119 may be electrically connected to the body contact region 111 at the top surface 111t. Similarly, another contact 119 may be electrically connected to the source contact region 113 at the top surface 113t. A contact 119 may be electrically connected to the drain contact region 109 at the top surface 109t. The contact 119 may be formed from a suitable conductive material, for example, copper, tungsten, or any other suitable conductive material. A gate dielectric layer 115 may be over a portion of the active region 102. For example, the gate dielectric layer 115 may be directly contacting a portion of the top surface 102t of the active region 102. In some embodiments, the gate dielectric layer 115 may extend from over a portion of the device well 105 to over a portion of the isolation region 107. For example, the gate dielectric layer 115 may be over a portion of the deep well region, with one end extending partially over the device well 105 and another opposite end extending partially over the isolation region. In an embodiment, the gate dielectric layer 115 may be over a portion of the device well 105 and may overhang a portion of the source contact region 113. The gate dielectric layer 115 may be over a portion of the deep well region 103 and extend over a substantial portion of the isolation region 107. For example, the gate dielectric layer 115 may directly contact the top surface 105t of the device well 105, the top surface 103t of the deep well region 103 and a substantial portion of the top surface 107t of the isolation region 107. A gate 117 may be over the gate dielectric layer 115. The gate dielectric layer 115 may be formed of a suitable dielectric material, for example, silicon dioxide, high dielectric constant material, or any other suitable dielectric material. The term “high dielectric constant material” may refer to a dielectric material having a dielectric constant higher than 7. The gate 117 may be formed from a suitable conductive material, for example, polysilicon, titanium nitride, tantalum nitride, or any other suitable conductive material.

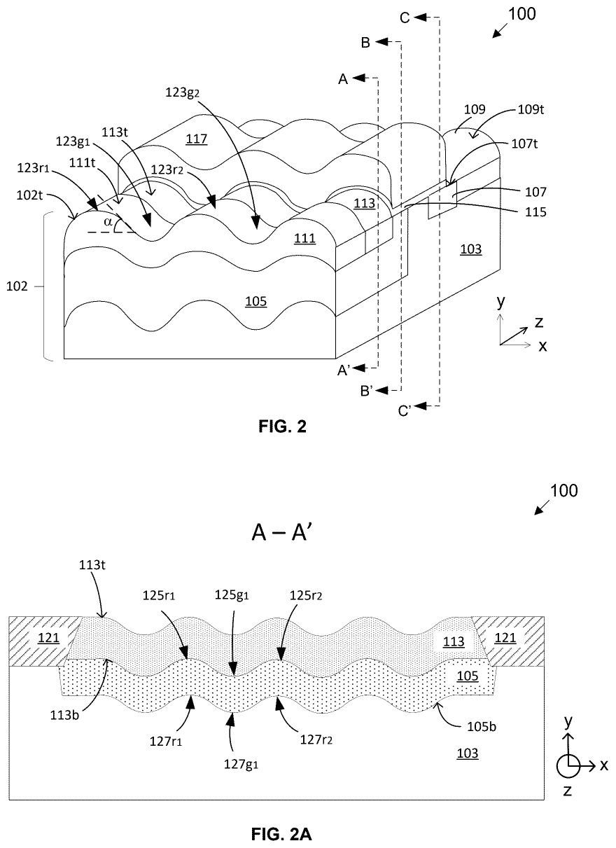

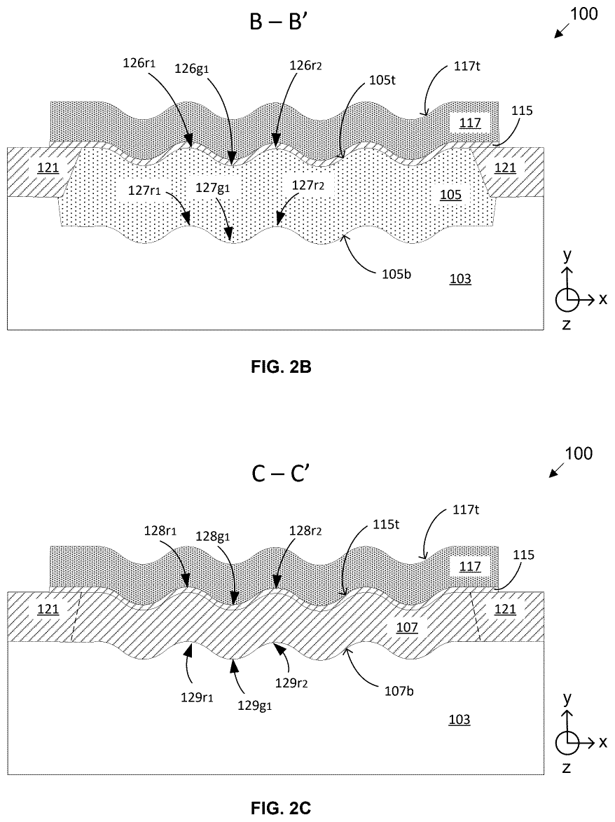

Now referring to FIG. 2 which shows a simplified three-dimensional view of the transistor 100, the active region 102 has a wavy top surface 102t comprising of parallel ridges, for example, ridge 123r₁ and ridge 123r₂, alternately arranged between parallel grooves, for example, groove 123g₁ and groove 123g₂. A ridge may be a raised curved surface having a curved convex profile and a groove may be a depressed surface having a curved concave profile. In some embodiments, ridge 123r₁ and ridge 123r₂ are raised surfaces adjacent to and connected to groove 123g₁ and groove 123g₂ which are depressed surfaces. In exemplary embodiments, ridge 123r₁ may be laterally adjacent to and directly connected to groove 123g₁, which may in turn be laterally adjacent to and directly connected to ridge 123r₂. In some embodiments, the ridge may have a side surface having a sidewall angle α of less than 70 degrees, for example, the side wall angle α of an exemplary ridge, for example, ridge 123r₁, may be less than 45 degrees. The ridges and grooves may be parallel to a direction transverse to the channel width. For example, the ridges and grooves may be parallel to the z-axis, while the channel width is along the x-axis. The channel width may be along the same direction as the gate width. In an embodiment, the ridges and grooves may be parallel to a direction along the channel length, which runs generally from the source contact region 113 to the drain contact region 109. The wavy top surface 102t may comprise of wavy top surfaces of the drain contact region 109, the isolation region 107, the body contact region 111 and the source contact region 113. In an embodiment, the wavy top surface 109t of the drain contact region 109, the wavy top surface 107t of the isolation region 107, the wavy top surface 111t of the body contact region 111 and the wavy top surface 113t of the source contact region 113 may be aligned to form a continuous surface formed of parallel ridges, for example ridge 123r₁ and ridge 123r₂, and parallel grooves, for example, 123g₁ and groove 123g₂. In some embodiments, the wavy top surface 102t may comprise parallel ridges and grooves extending from the body contact region 111 to the drain contact region 109, and the ridges and grooves are alternately arranged.

Next referring to FIG. 2A which shows a simplified cross-sectional view of the transistor 100 across line A-A′ in FIG. 2, the source contact region 113 and the device well 105 may be between isolation structures 121, which provides electrical isolation for the transistor device from the rest of the substrate. In an embodiment, isolation structures 121 may be shallow trench isolation (STI) structures. The source contact region 113 may have a bottom interface 113b with the device well 105. In an embodiment, the bottom interface 113b may be wavy, having ridges and grooves arranged in alternating fashion. For example, ridge 125r₁ is laterally adjacent to and directly connected to groove 125g₁, and groove 125g₁ is laterally adjacent to and directly connected to ridge 125r₂. In some embodiments, the ridges and grooves are parallel to each other and arranged in a direction along the channel length and transverse to the channel width. The device well 105 may have a bottom interface 105b with the deep well region 103. In an embodiment, the bottom interface 105b may be wavy, having alternating ridges and grooves, for example, ridge 127r₁ is laterally adjacent to and directly connected to groove 127g₁, and groove 127g₁ is laterally adjacent to and directly connected to ridge 127r₂. The ridges and grooves for bottom interface 113b may be vertically aligned with corresponding ridges and grooves for bottom interface 105b. Vertically aligned may mean that two or more corresponding features are vertically above or below each other generally along the same y-axis. For example, ridge 125r₁ on the bottom interface 113b may be vertically above ridge 127r₁ on the bottom interface 105b, and groove 125g₁ on the bottom interface 113b may be vertically above groove 127g₁ on the bottom interface 105b.

FIG. 2B shows a simplified plan-view of a section of a transistor 100 across line B-B′ in FIG. 2. The device well 105 may be between isolation structures 121 and have a top surface 105t that is in direct contact with the gate dielectric layer 115 and a bottom interface 105b with the deep well region 103. The top surface 105t and bottom interface 105b may each be wavy and may each have parallel ridges and grooves alternately arranged. In an embodiment, the top surface 105t may be wavy, having alternating ridges and grooves, for example, ridge 126r₁ is laterally adjacent to and directly connected to groove 126g₁, and groove 126g₁ is laterally adjacent to and directly connected to ridge 126r₂. In an embodiment, ridges and grooves on the top surface 105t may be vertically aligned with corresponding ridges and grooves on the bottom interface 105b. For example, ridge 126r₁ on the top surface 105t may be vertically above ridge 127r₁ on the bottom interface 105b, and groove 126g₁ on the top surface 105t may be vertically above groove 127g₁ on the bottom interface 105b.

Still referring to FIG. 2B, the gate dielectric layer 115 may extend from a top surface of the isolation structures 121 and over the top surface 105t of the device well 105. The gate dielectric layer 115 may have a wavy structure conformal to the top surface 105t of the device well 105. A gate 117 may be over the gate dielectric layer 115, extend from above a top surface of a first isolation structure 121, over the device well 105, to a top surface of another isolation structure 121 opposite to the first isolation structure 121. The gate 117 may have a wavy structure, with parallel ridges and grooves alternately arranged. The ridges and grooves of the gate 117 may be vertically aligned to the corresponding ridges and grooves of the top surface 105t of the device well 105. In some embodiments, the ridges and grooves of the gate 117 may be vertically aligned to the corresponding ridges and grooves of the bottom interface 105b of the device well 105.

Next referring to FIG. 2C, which shows a simplified plan-view of a section of a transistor 100 across line C-C′ in FIG. 2. The isolation region 107 may be between isolation structures 121 and have a bottom interface 107b with the deep well region 103. In some embodiments, the bottom interface 107b of the isolation region 107 may be at least as deep as the depth of the isolation structures 121. For example, the bottom most depth of the isolation region 107 may be at the same depth or lower than the depth of the isolation structures 121. The gate dielectric layer 115 may be between the isolation region 107 and the gate 117. The gate dielectric layer 115 may have a top surface 115t in direct contact with the bottom surface of the gate 117. The top surface 115t of the gate dielectric layer 115 and the bottom interface 107b of the isolation region 107 may each be wavy and may each have parallel ridges and grooves alternately arranged. For example, for the top surface 115t of the gate dielectric layer 115, ridge 128r₁ is laterally adjacent to and directly connected to groove 128g₁, and groove 128g₁ is laterally adjacent to and directly connected to ridge 128r₂. For the bottom interface 107b of the isolation region 107, ridge 129r₁ is laterally adjacent to and directly connected to groove 129g₁, and groove 129g₁ is laterally adjacent to and directly connected to ridge 129r₂. In some embodiments, ridges and grooves on the top surface 115t of the gate dielectric layer may be vertically aligned with corresponding ridges and grooves on the bottom interface 107b of the isolation region 107. For example, ridge 128r₁ on the top surface 115t of the gate dielectric layer 115 may be vertically above ridge 129r₁ on the bottom interface 107b of the isolation region 107, and groove 128g₁ on the top surface 115t may be vertically above groove 129g₁ on the bottom interface 107b. In some embodiments, the ridges and grooves of the gate 117 may be vertically aligned to the corresponding ridges and grooves of the bottom interface 107b of the isolation region 107.

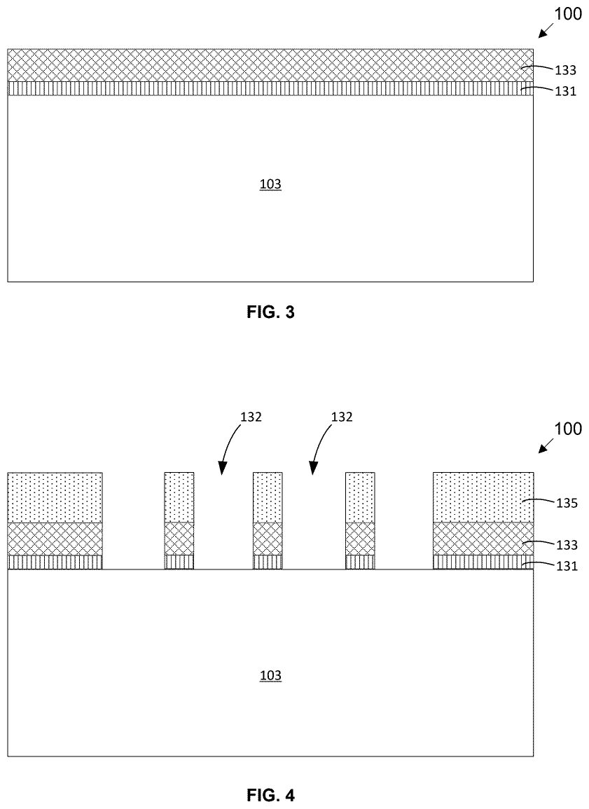

FIG. 3-12B illustrate an exemplary process flow for fabricating the section of transistor 100 shown in FIG. 1, according to exemplary embodiments of the invention. First referring to FIG. 3, a substrate 101 (not shown) including a deep well region 103 is provided. Deep well region 103 may be formed by suitable methods, including epitaxial growth or well implant. In some embodiments, the deep well region 103 may be formed at a later stage of the device processing, for example, after the formation of isolation structures 121. An oxide layer 131 may be formed over the deep well region 103, for example, by a thermal oxidation process. A nitride layer 133 may be formed over the oxide layer 131 by a deposition process, for example, chemical vapor deposition (CVD), plasma enhanced chemical vapor deposition (PECVD) and physical vapor deposition (PVD). In some embodiments, the oxide layer 131 may be a silicon oxide layer having a thickness of about 80 Angstroms and the nitride layer 133 may be a silicon nitride layer having a thickness in the range of about 500 to 2000 Angstroms.

FIG. 4 shows a subsequent processing step where the nitride layer 133 and oxide layer 131 have been patterned using a photoresist mask 135. The photoresist mask 135 may be patterned to form openings 132, through which the exposed sections of the nitride layer 133 and oxide layer 131 are removed by a suitable material removal process, in turn exposing portions of the top surface of the deep well region 103. Examples of material removal processes include anisotropic dry etch and plasma etch processes. The photoresist mask 135 may be removed after the patterning process is completed.

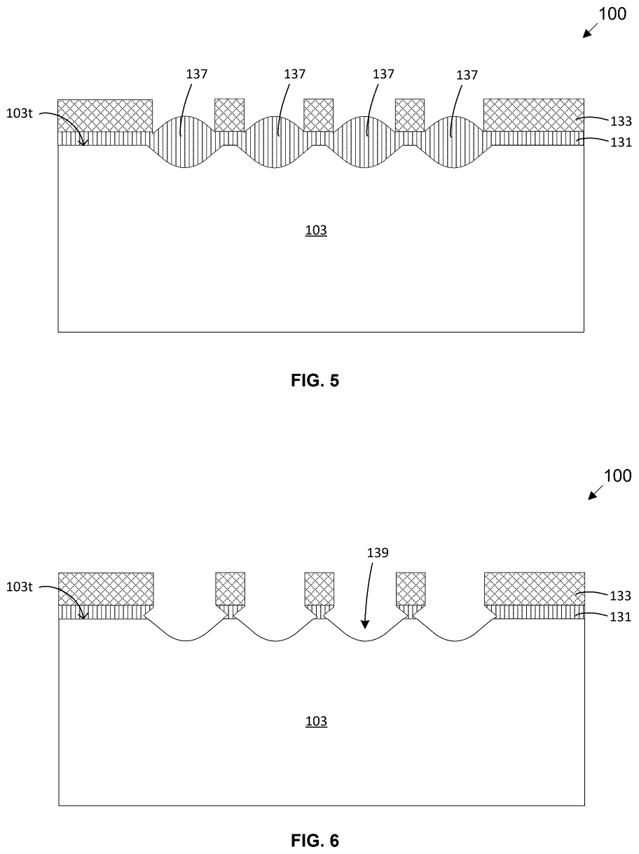

Next referring to FIG. 5 which shows the section of the transistor 100 after performing a subsequent thermal oxidation process, forming LOCOS (local oxidation of silicon) structures 137 on the portions of the top surface of the deep well region 103 that are exposed or uncovered by the patterned nitride layer 133 and oxide layer 131. In some embodiments, the thermal oxidation process may be a thermal annealing process performed in an oxidizing environment at a temperature between 700 degree Celsius to 1000 degree Celsius, for a duration of between 1 minute to 180 minutes. The LOCOS structures 137 extend above and below the top surface 103t of the deep well region 103, having curved top and bottom surfaces. In some embodiments, the end side portions of the LOCOS structures extend laterally underneath the patterned nitride layer 133 and oxide layer 131, and the end side portions of the LOCOS structures may each have a curved bird's beak profile.

FIG. 6 shows the section of the transistor 100 after a subsequent material removal step to remove the LOCOS structures 137 from the top surface of the deep well region 103, forming depressions or grooves 139 in the top portion of the deep well region 103. Examples of a suitable material removal step include wet etching, for example with an acid etchant at elevated temperatures. In some embodiments, the depressions or grooves 139 have a curved profile, for example, a curved concave profile.

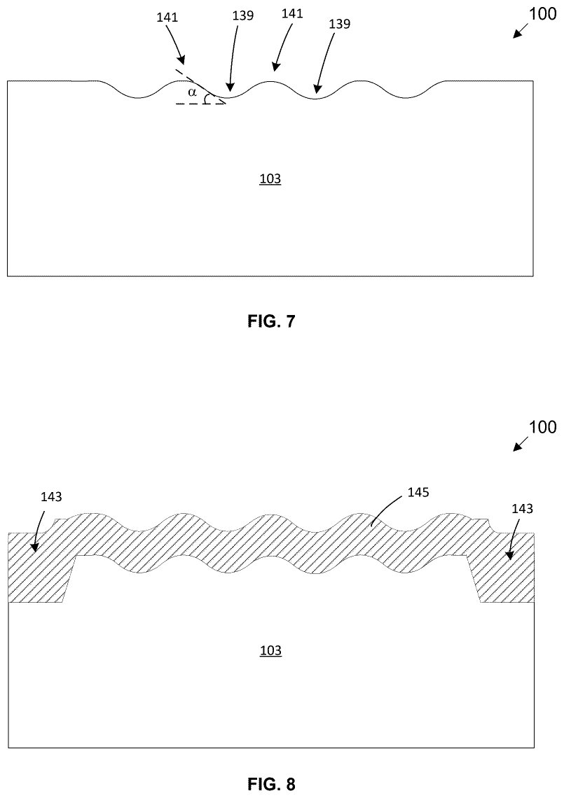

In a subsequent processing step as shown in FIG. 7, the patterned nitride layer 133 and oxide layer 131 are stripped from the surface of the deep well region 103, using suitable material removal processes. Examples of suitable material removal processes include performing a wet etch with an acid etchant at elevated temperatures, such as hot phosphoric acid, followed by a conventional etch in diluted or buffered acid etchant such as hydrofluoric acid. The resulting top surface 103t of the deep well region 103 may have a wavy structure, comprising ridges 141 and adjacent grooves 139 arranged in an alternating fashion. Each ridge may be directly connected to an adjacent groove and each groove may be directly connected to an adjacent ridge to form a continuous wavy surface. In some embodiments, each ridge may have a sidewall angle α of less than 70 degrees. In other embodiments, the side wall angle α of an exemplary ridge, for example, ridge 141, may be less than 45 degrees.

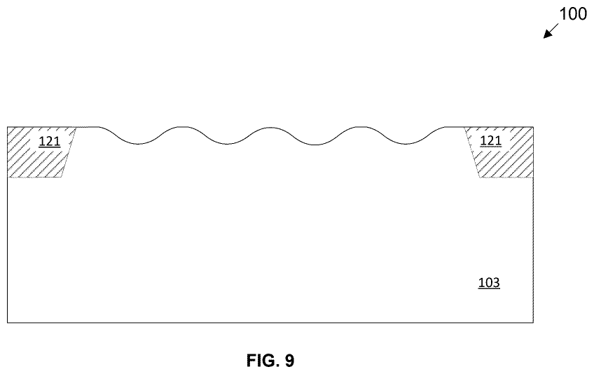

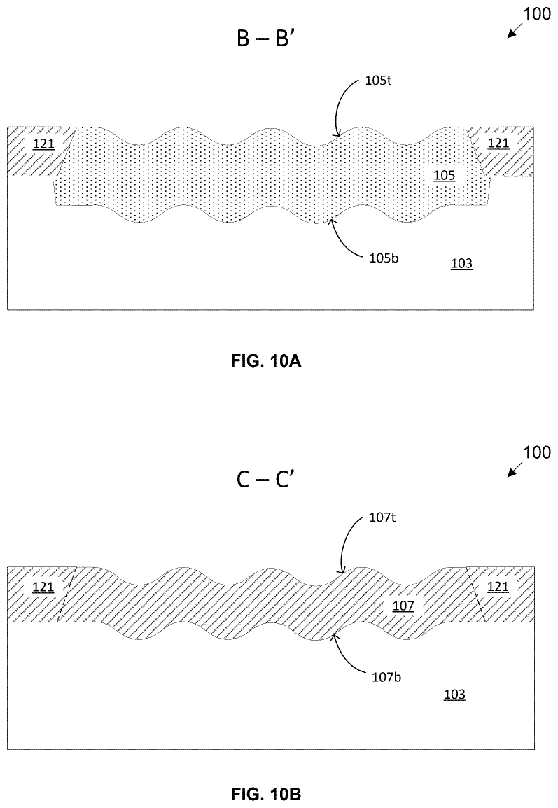

Next referring to FIGS. 8 and 9 which show the section of the transistor 100 after forming isolation trenches 143 and an oxide layer 145, and subsequent processing to form isolation structures 121. The isolation trenches 143 are first patterned and formed in the deep well region 103, and the oxide layer 145 is formed in the isolation trenches and over the top surface of the deep well region 103. One or more masks (not shown) may be required to form the trenches and may be left in place during the oxide layer formation in some embodiments. The oxide layer 145 may be formed by a thermal oxidation process or by deposition. One or more material removal processes may be performed to remove any excess material, leaving behind the isolation structures 121 shown in FIG. 9, surrounding the wavy top surface of the deep well region 103.

FIGS. 10A and 10B show simplified cross-sectional views of intermediate structures of a section of a transistor 100 after additional processing, corresponding to the midstream process structures of the section of the transistor 100 in FIG. 2 across line B-B′ and line C-C′ respectively, according to an exemplary embodiment of the disclosure. First referring to FIG. 10A, a device well 105 is formed by a suitable implantation process into the surface of the deep well region 103. For example, for a N-type LDMOS transistor, the device well 105 may be a P-type body region, and a suitable P-type dopant may be chosen for the implantation process. The implant dosage and implant energy may be selected according to the desired breakdown voltage for the LDMOS transistor. Implantation through the wavy top surface of the deep well region 103 may result in the device well 105 having a wavy bottom interface 105b with the deep well region 103, and a wavy top surface 105t having alternating ridges and grooves vertically aligned with corresponding ridges and grooves on the bottom interface 105b. Now referring to

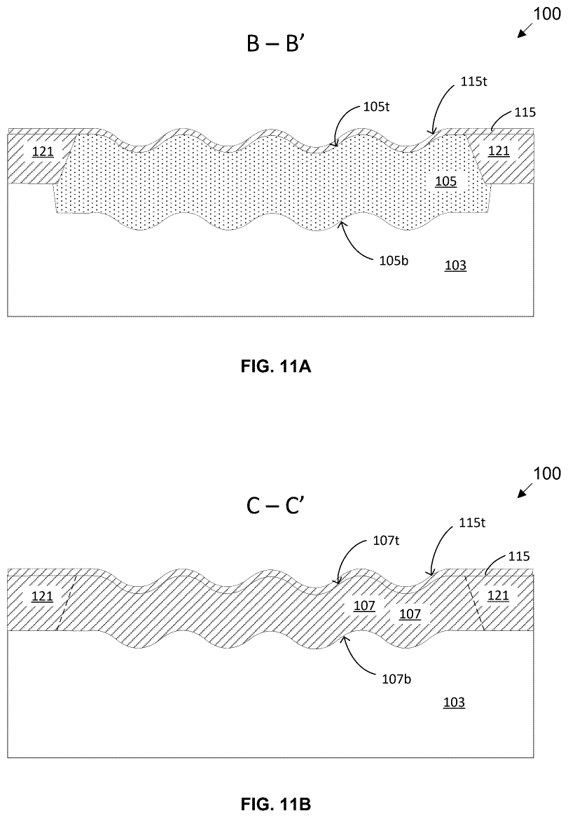

FIGS. 11A and 11B show simplified cross-sectional views of intermediate structures of a section of a transistor 100 after additional processing, corresponding to the midstream process structures of the section of the transistor 100 in FIG. 2 across line B-B′ and line C-C′ respectively, according to an exemplary embodiment of the disclosure. A gate dielectric layer 115 is formed over the top surface 105t of the device well 105, the top surface 107t of the isolation region 107 and the top surfaces of the isolation structures 121. The gate dielectric layer 115 has an even thickness and is conformal to the wavy top surfaces of the device well 105 and the isolation region 107, resulting in the gate dielectric layer 115 similarly having a wavy top surface 115t, having alternating ridges and grooves vertically aligned with corresponding ridges and grooves on the bottom interface 105b of the device well 105, and a wavy bottom interface 107b of the isolation region 107, respectively. In an embodiment, the gate dielectric layer 115 may be formed by an oxidation process.

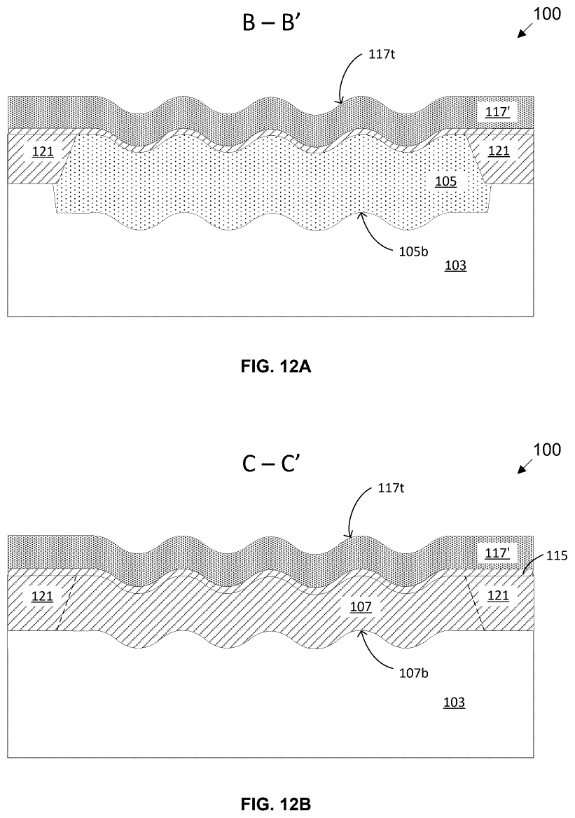

FIGS. 12A and 12B show simplified cross-sectional views of intermediate structures of a section of a transistor 100 after additional processing, corresponding to the midstream process structures of the section of the transistor 100 in FIG. 2 across line B-B′ and line C-C′ respectively, according to an exemplary embodiment of the disclosure. A conductive layer 117′ is formed over the wavy top surface 115t of the gate dielectric layer 115 and also over the gate dielectric layer 115 on the isolation structures 121. The wavy top surface 115t of the gate dielectric layer 115 may thus be in direct contact with the bottom surface of the conductive layer 117'. The resulting conductive layer 117′ may also have a wavy top surface 117t, having alternating ridges and grooves vertically aligned with corresponding ridges and grooves on the bottom interface 105b of the device well 105, and a wavy bottom interface 107b of the isolation region 107, respectively. Subsequently, using suitable masks and material removal processes, the conductive layer 117′ is patterned to form gate 117, extending from over a portion of the device well 105 to over a portion of the isolation region 107, as shown in FIG. 2. Further implantation processes are performed through selected sections of the wavy top surface 102t of the active region 102, to form the source contact region 113, the body contact region 111 and the drain contact region 109 of the section of transistor 100 shown in FIG. 1-2C. The body contact region 111 and the source contact region 113 may each be formed by a suitable implantation process through the wavy top surface of the device well 105, while the drain contact region 109 may be formed by a suitable implantation process through the wavy top surface of the deep well region 103. Masks for protecting selected regions of the device well 105 and the deep well region 103 may be required during the implantation processes. In some embodiments, the body contact region 111 may have the same dopant polarity. For example, for a N-type LDMOS transistor, the device well 105 may be a P-type body region, and the body contact region may also have p-type dopants and as such, a suitable p-type dopant may be chosen accordingly for the implantation process. The source contact region 113 and the drain contact region 109 may have the same dopant polarity. For example, for a N-type LDMOS transistor, suitable n-type dopants may be chosen for the source contact region 113 and the drain contact region 109. Implantation through the wavy top surface of the device well 105 may result in the source contact region 113 having a wavy bottom interface 113b with the device well 105, and a wavy top surface 113t having alternating ridges and grooves vertically aligned with corresponding ridges and grooves on the bottom interface 113b. Accordingly, the implantation process for the body contact region 111 through the wavy top surface of the device well 105 may also result in the body contact region 111 having a wavy bottom interface 111b with the device well 105, and a wavy top surface 111t having alternating ridges and grooves vertically aligned with corresponding ridges and grooves on the bottom interface 111b. Similarly, implantation through the wavy top surface of the deep well region 103 may result in the drain contact region 109 having a wavy bottom interface 109b with the deep well region 103, and a wavy top surface 109t having alternating ridges and grooves vertically aligned with corresponding ridges and grooves on the bottom interface 109b.

Descriptions of embodiments herein are meant to be taken as examples and not meant to be limiting as such. Terms such as “vertical”, “horizontal”, “top”, “bottom”, “over”, “under”, and the like in the description and in the claims, if any, are used for establishing a frame of reference and not necessarily for describing permanent relative positions. The term “horizontal” is defined as a plane parallel to a conventional plane of a semiconductor substrate, rather than its actual three-dimensional orientation in space. The terms “vertical” and “normal” refer to a plane perpendicular to the horizontal. The term “lateral” refers to a direction parallel to the horizontal plane.

Terms such as “connected” or “coupled” indicate that a feature may be directly connected or coupled to or with the other feature, or one or more intervening features may also be present. A feature may be “directly connected” or “directly coupled” to or with another feature if intervening features are absent. A feature may be “indirectly connected” or “indirectly coupled” to or with another feature if at least one intervening feature is present. Terms such as “on” or “contacting” indicate that a feature may be directly on or in direct contact with the other feature, or one or more intervening features may also be present. A feature may be “directly on” or in “direct contact” with another feature if intervening features are absent. A feature may be “indirectly on” or in “indirect contact” with another feature if at least one intervening feature is present.

The terms “first”, “second”, “third” and the like in the description and in the claims, if any, are used for distinguishing between similar elements and not necessarily for describing a particular sequential or chronological order as required. A method described herein is not necessarily limited in practice to the exact order or number of steps as have been listed, and certain steps may possibly be omitted and/or certain other steps not described herein may possibly be performed in actual practice. Terms such as “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in one embodiment” herein do not necessarily all refer to the same embodiment.

While several exemplary embodiments have been presented in the above detailed description of the device, it should be appreciated that number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

What is claimed is:

1. A transistor comprising:
a deep well region comprising a device well, a drain contact region, an isolation region adjacent to the drain contact region, a body contact region and a source contact region adjacent to the body contact region;
a gate dielectric layer over a portion of the deep well region, the gate dielectric layer extending partially over the device well and partially over the isolation region; and
a gate electrode over the gate dielectric layer, wherein the device well, the drain contact region, the isolation region, the body contact region and the source contact region each has a wavy top surface.

2. The transistor of claim 1, wherein the device well has a wavy bottom interface with the deep well region.

3. The transistor of claim 1, wherein the isolation region has a wavy bottom interface with the deep well region.

4. The transistor of claim 1, wherein the source contact region has a wavy bottom interface with the device well.

5. The transistor of claim 1, wherein the wavy top surfaces of the drain contact region, the isolation region, the device well, the body contact region and the source contact region are all aligned to form a continuous surface formed of parallel ridges and grooves.

6. The transistor of claim 1, further comprising a channel region having a channel width, wherein the wavy top surface comprises parallel ridges and grooves along a direction transverse to the channel width.

7. The transistor of claim 3, wherein the wavy bottom interface with the deep well region comprises parallel ridges and grooves.

8. The transistor of claim 7, further comprising a channel region having a channel length extending from source contact region to the drain contact region, wherein the ridges and grooves are parallel to a direction along the channel length.

9. The transistor of claim 1, wherein the deep well region, the source contact region and the drain contact region have dopants of a first polarity, and the device well and body contact region have dopants of a second polarity different from the first polarity.

10. A laterally diffused metal oxide semiconductor (LDMOS) transistor comprising:
an active region comprising
a deep well region, the deep well region comprising a drain contact region, an isolation region adjacent to the drain contact region, a device well including a body contact region and a source contact region adjacent to the body contact region;
a gate dielectric layer over a portion of the active region, the gate dielectric layer extending partially over the device well and partially over the isolation region; and
a gate electrode over the gate dielectric layer, wherein
the active region has a wavy top surface comprising of parallel ridges and grooves extending from the body contact region to the drain contact region and the parallel ridges and grooves are alternately arranged.

11. The transistor of claim 10, wherein the device well has a wavy bottom interface with the deep well region.

12. The transistor of claim 10, wherein the isolation region has a wavy bottom interface with the deep well region.

13. The transistor of claim 12, wherein the wavy bottom interface with the deep well region comprises parallel ridges and grooves.

14. The transistor of claim 10, wherein the source contact region has a wavy bottom interface with the device well.

15. The transistor of claim 10, further comprising a channel region having a channel length extending from source contact region to the drain contact region, wherein the ridges and grooves are parallel to a direction along the channel length.

16. A method of fabricating a semiconductor device comprising:
forming a deep well region in a substrate;
forming a wavy top surface for the deep well region;
forming a device well within the deep well region;
forming an isolation region within the deep well region;
forming a gate dielectric layer over a portion of the deep well region, the gate dielectric layer extending partially over the device well and partially over the isolation region;
forming a gate electrode over the gate dielectric layer;
forming a drain contact region within the deep well region;
forming a body contact region within the device well;
forming a source contact region within the device well, adjacent to the body contact region;
and wherein the drain contact region, the isolation region, the device well, the body contact region and the source contact region each has a wavy top surface.

17. A method according to claim 16 wherein the forming a wavy top surface for the deep well region comprises a thermal oxidation process.

18. A method according to claim 16 wherein the forming a wavy top surface for the device well comprises a local oxidation of silicon (LOCOS) process.

19. A method according to claim 16 wherein the forming an isolation region within the deep well region comprises a local oxidation of silicon (LOCOS) process.

20. A method according to claim 16 wherein the forming a device well within the deep well region comprises:
forming isolation trenches in the deep well region; and
performing an implantation process on the wavy top surface to form the device well, where the device well has a wavy bottom interface with the deep well region.
